(19) United States
(12) Patent Application Publication
(10) Pub. No.: US 2011/0122675 A1
(43) Pub. Date: May 26, 2011

(54) Programmable Resistance Memory

(76) Inventor: Ward Parkinson, Boise, ID (US)

(21) Appl. No.: 12/626,234

(22) Filed: Nov. 25, 2009

(51) Int. Cl. G11C 7/10; G11C 11/00; G11C 7/00

(52) U.S. Cl. 365/148; 365/163; 365/189.05; 365/189.15; 365/189.16

(57) ABSTRACT

A nonvolatile memory includes write circuitry that writes to a selected memory element and, in parallel, to a data latch. The memory is configured to compare the current memory address to the previous memory address and to enable a read operation from the data latch rather than a selected memory element if the current and previous memory addresses are the same.

### FIELD OF INVENTION

This invention relates to electronic memory devices and, in particular, to nonvolatile integrated circuit memories.

### BACKGROUND OF THE INVENTION

The process of accessing an integrated circuit memory is typically a multi-step process during which delays or wait-states are introduced in order to permit signal lines to settle into a stable condition before the access proceeds. Address, data, read, write, chip select, and enable lines may all be asserted in an orchestrated sequence that ensures that data and address signals are valid when data is latched into or out of the memory. Such delays must be minimized in order to permit high-speed memory and system operation.

Despite efforts to improve memory speed, many design requirements for on-chip memory cells adversely affect their speed. For example, integrated circuit memories often employ a multiplexed addressing scheme in order to accommodate a large access space with a limited device pinout. The multiplexed address lines are typically referred to as row and column address lines, reflecting the rectangular arrangement of memory element placement typical of integrated circuit memory arrays. When accessing such a memory, the row addresses are typically asserted and trapped in registers before the column addresses are asserted and used.

Because nonvolatile integrated circuit (“IC”) memories tend to be somewhat slower than volatile IC memories, additional delays, such as those associated with sequentially asserting row and column address lines impose additional design limitations on the use of nonvolatile memories at speeds closer to volatile memories. A nonvolatile memory that provides for higher-speed access would be particularly desirable.

### SUMMARY

In an illustrative method in accordance with the principles of the present invention, a nonvolatile integrated circuit memory writes information, in parallel, to a selected memory element and to a register. If the access operation immediately following the write operation is a read operation and the same memory element is accessed, the information is read from the register, rather than from the memory element. In an illustrative embodiment, the nonvolatile memory includes “full” and “accelerated” access modes and the register is read only when the above conditions apply and, additionally, the memory is operating in its accelerated access mode. An accelerated access mode may take the form of a page mode access, for example.

In a page mode access, one set of address line values, which define a page of memory, remain unchanged during a sequence of accesses while the remaining address line values, which define individual memory elements within a page, are altered to access individual cells within the page. Because the address values that define the page are not altered, the setup time normally associated with accessing the page may be eliminated and access may be provided to locations within a page at a much higher rate than accesses to memory elements located in different pages; access is accelerated in this sense. In an illustrative embodiment, a nonvolatile memory in accordance with the principles of the present invention reads data back from the parallel storage register only when the current read address is identical to the immediately previous address at which a write operation was performed. In another illustrative embodiment, a nonvolatile memory in accordance with the principles of the present invention reads data back from the parallel storage register whenever the current address falls within the same page as the previous address and the address defining the selected page has been held constant since the previous access (thereby allowing the faster read or write access).

A nonvolatile memory in accordance with the principles of the present invention may be a programmable resistance memory, such as a phase change memory, for example. A nonvolatile memory in accordance with the principles of the present invention includes write circuitry that writes to a selected memory element and, in parallel, to a data latch. Additionally, the memory includes circuitry configured to compare the current memory address to the previous memory address and to enable a read operation from the data latch rather than a selected memory element if the current and previous memory addresses are the same.

A nonvolatile memory that employs a parallel write scheme in accordance with the principles of the present invention may be particularly suitable for operation in a variety of electronic devices, including cellular telephones, radio frequency identification devices (RFID), computers (portable and otherwise), solid state drives (SSDs), location devices (e.g., global positioning system (GPS) devices, particularly those that store and update location-specific information), and handheld electronic devices, including personal digital assistants (PDAs), and entertainment devices, such as MP3 players, for example.

### BRIEF DESCRIPTION OF THE DRAWINGS

FIG. 1 is a block diagram of an integrated circuit nonvolatile memory that includes an array of nonvolatile memory elements and read and write circuitry;

FIG. 2 is a flow chart that outlines access operations of a nonvolatile memory in accordance with the principles of the present invention;

FIG. 3 is a more detailed block diagram of an integrated circuit nonvolatile memory in accordance with the principles of the present invention; and

FIG. 4 is a block diagram of an electronics system that operates in accordance with the principles of the present invention.

### DETAILED DESCRIPTION

Although this invention will be described in terms of certain preferred embodiments, other embodiments that are apparent to those of ordinary skill in the art, including embodiments that do not provide all of the benefits and features set forth herein, are also within the scope of this invention. Various structural, logical, process step, chemical, and electrical changes may be made without departing from the spirit or scope of the invention. Polarities and types of devices and supplies may be substituted in a manner that would be apparent to one of reasonable skill in the art. Process descriptions may include flowcharts that illustrate various steps taken in a process. Such flowcharts and accompanying discussion are not meant to be an exhaustive explanation of every step and every procedure in such a process. Rather, they are meant to provide a description with sufficient detail to enable one of ordinary skill in the art to practice and use the invention. In some embodiments, additional steps may be employed or steps may be carried out in a different sequence than set forth in the flowchart and associated discussion. Accordingly, the scope of the invention is defined only by reference to the appended claims.

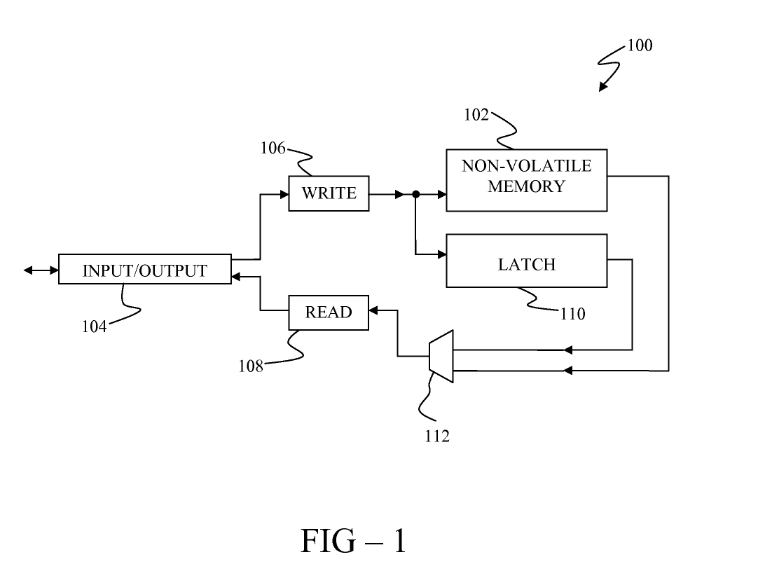

The block diagram of FIG. 1 illustrates components of a nonvolatile memory 100 in accordance with the principles of the present invention. The nonvolatile memory 100 includes a memory cell or an array of nonvolatile memory elements 102 which may be arranged in one or more rectangular hierarchical arrays. Cells within the array 102 may be accessed through input/output (I/O) circuitry 104. I/O circuitry 104 may include address lines, data lines, a read signal line, a write signal line, and various chip enable and strobe lines, for example. The I/O circuitry 104 provides an interface between off-chip and on-chip circuitry and, in particular, between off-chip circuitry and on-chip write circuitry 106 and on-chip read circuitry 108.

In accordance with the principles of the present invention, the nonvolatile memory 100 includes a data latch 110 to which data is written in parallel with data written to an addressed memory element within the memory array 102. As indicated by the multiplexor 112, the read circuitry 108 is configured to selectively read from either the memory array 102 or from the data latch 110 by connecting either an addressed memory element or the data latch 110 to a sense amplifier within the read circuitry 108. As described in greater detail in the discussion related to the following figures, data may be read sooner from the data latch 110, for example, if the memory is engaged in an accelerated access mode of operation, such as a page mode.

Although cells within the memory array 102 may be any type of nonvolatile memory, in an illustrative embodiment the cells are programmable resistance memory elements. Such programmable resistance memory elements may be implemented as phase change memory elements, for example. Phase change memories are known and described, for example, in U.S. Pat. Nos. 6,859,390; 6,774,387; 6,687,153; and 6,314,014, the disclosures of which are hereby incorporated by reference.

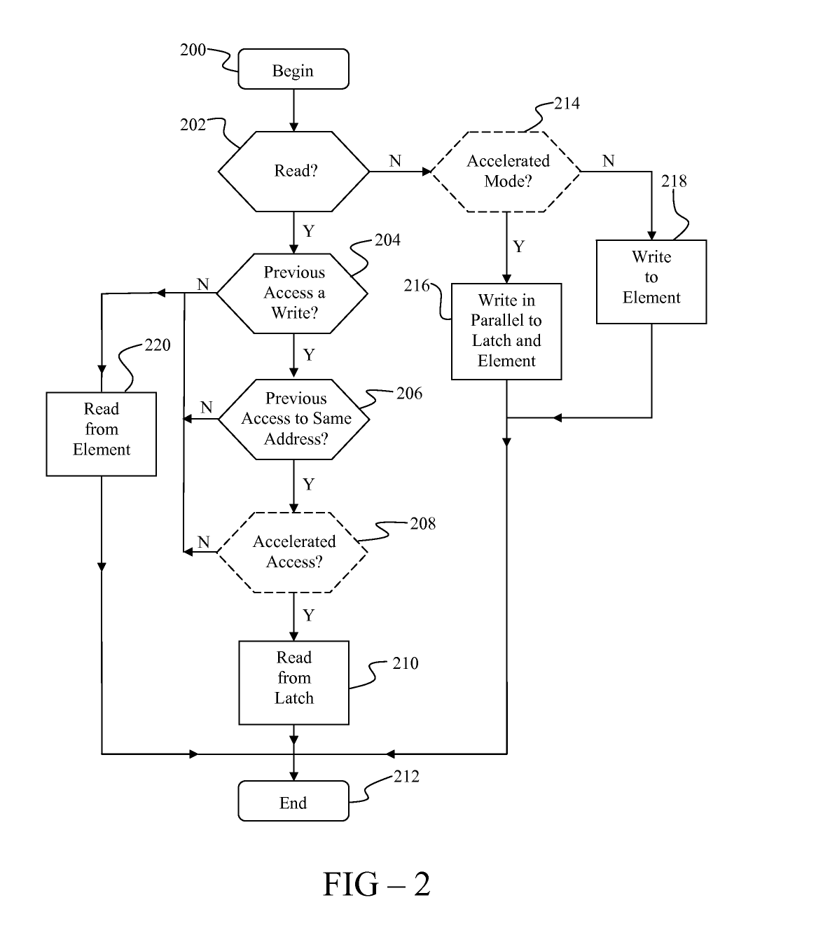

The process of accessing a nonvolatile memory in accordance with the principles of the present invention is depicted in the flow chart of FIG. 2. The process begins in step 200 and proceeds from there to step 202, where the memory determines whether the current access operation is a read operation. If the current operation is a read operation, the process proceeds to step 204, where the memory determines whether the immediately prior access operation was a write operation. If the immediately prior access operation was a write operation, the process proceeds to step 206 where the memory determines whether the immediately prior access operation was performed on a memory element at the same address as the current address.

If the immediately prior access operation was performed on a memory element at the same address as the current access operation, the process proceeds to optional step 208, where the memory determines whether it is operating in an accelerated mode. One example of an accelerated access mode is a page mode, whereby accesses are performed on different memory elements within the same page of memory. Because only one set of the multiplexed addresses is updated in a page mode access, the setup time required for those addresses that are not updated is eliminated and different memory elements may be accessed much more rapidly, either sequentially or in random order within the page (the X address held constant during changes in the Y address). In this illustrative embodiment, if the memory is operating in an accelerated mode, such as a page mode, the process proceeds to step 210 where data is read from the data latch to which data was last written in parallel with writing to an accessed memory element. The writing aspect of this illustrative process is described in the discussion related to steps 214, 216, and 218. From step 210 the process proceeds to end in step 212. The order of 204 and 206 may be reversed or done in parallel. Similarly, step 208 may be reversed with 204 or 206, or also done in parallel.

In other embodiments in accordance with the principles of the present invention the memory doesn't determine whether it is operating in an accelerated mode, it simply reads from a data latch anytime the same memory element is read immediately after having been written to in the previous access operation. Additionally, when the address of the current access operation is compared to the address of the immediately prior access operation, the memory may optionally compare only a portion of the addresses so that, for example, any read immediately following a write access within the same page triggers a read from the data latch rather than from the addressed memory element.

Returning to step 202, if the access operation is not a read operation, the process proceeds to optional step 214 where the memory determines whether it is operating in an accelerated mode, such as page mode. A user may supply a signal to the memory to indicate that it is to operate in an accelerated mode, such as page mode. In applications where such a signal is unavailable, the memory may employ accelerated mode as a default mode. If the memory is operating in an accelerated mode, the process proceeds to step 216, where the memory writes data to the addressed memory element and to a data latch in parallel (for example, to a D flip-flop or equivalent). From step 216, the process proceeds to end in step 212.

As described in the discussion related to step 210, data may be read from a data latch, rather than from an addressed memory element, when, for example, the identical memory element is accessed for read that had been written to in the previous write access operation. Such reading from the latch instead of from the memory element may be also limited to when the memory is operating in an accelerated access mode. Such reading from the latch may be limited to an access immediately after write or after reading from different locations after the write, so long as the latch is read only when the address is the same as the last memory cell written.

Reading from the data latch rather than from an addressed memory element that had been written to in an immediately prior access operation allows for stabilization of the data written into the memory element before the data is read. Reading from a data latch, rather than a selected memory element allows for speedier access in an accelerated access mode, consistent, for example, with page mode access of a DRAM. In a nonvolatile memory in accordance with the principles of the present invention, such as when using a phase change memory, for example, specified access times may be set according to an access mode that allows sequential setup times for both row and column addresses. Although a write access by the user may require less than the thus-specified access time set by the bus delays and margin for setup and hold times, data written to a memory cell may require some settling time before it may be reliably read. Even if the settling time from writing a selected memory element is less than the period determined, for example, by sequentially multiplexed row and column address setup times, it may be greater than either a row or a column address time. In an accelerated access mode, such as page mode, where a read access may allow for only a column address setup and hold time, data written to a memory element may not have completely settled before a subsequent read access period arrives after the write cycle. Reading from a latch under such circumstances ensures that valid data is available, even in accelerated access modes, and without additional delay for memory settling time after a write.

Returning to step 214, if the memory determines that it is not operating in an accelerated access mode, such as a page mode, the process proceeds to step 218. In DRAM operation, for example, the access may be signaled as not accelerated by Ras going high after write is initiated (by WE going low) but before the write cycle is started on-chip. Then, the memory writes to the addressed memory element only and latch is not necessary. That is, in this illustrative embodiment, the memory only writes to the addressed memory and data latch in parallel when it is operating in an accelerated access mode, such as a page mode. If the latch is not written, the chip must may be presumed to not be in accelerated mode thereafter, since otherwise the latch may have incorrect data if used for reading. Alternatively, the latch may be written whether in accelerated or not in accelerated mode.

Other embodiments of a nonvolatile memory access process in accordance with the principles of the present invention, processes during which the memory writes to a data latch in parallel with the addressed memory for all write operations, or processes during which the memory writes to a data latch and addressed memory in parallel in modes other than accelerated access modes, for example, are contemplated within the scope of the present invention. From step 218 the process proceeds to end in step 212.

Returning to step 204, if the immediately prior access operation was not a write operation, the process proceeds to step 220 where the memory chip reads from the addressed memory element. In this illustrative embodiment, the memory retrieves data from an addressed memory element if the immediately prior access operation was not a write operation. If the immediately prior access operation was not a write operation, at least one access period has fallen between the most recent write access operation and the current read operation and, in this illustrative embodiment, sufficient time has transpired for any written data to have settled to a steady state suitable for reading and data is therefore read from the addressed memory element, rather than from the data latch. From step 220 the process proceeds to end in step 212. In the alternative, if the previous access was not a write but the address is the same as the last write, the memory may be read from either memory element or from the latch (if the latch is written on each write cycle).

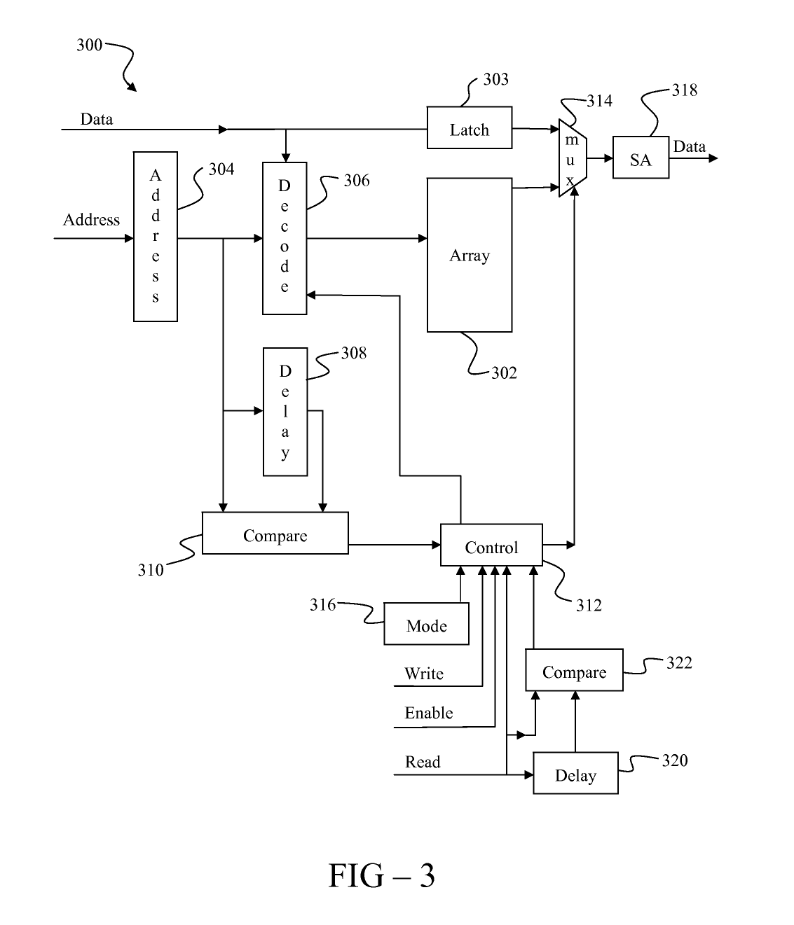

The block diagram of FIG. 3 provides a more-detailed view of a nonvolatile memory in accordance with the principles of the present invention. The memory 300 includes nonvolatile memory elements 302 which may be arranged in a hierarchical crosspoint rectangular array and accessed by multiplexed address lines split into row and column address lines, which are provided at either the same time (as in Sram or Flash) or at different times (as in Dram). In such an embodiment, the separately decoded row and column address lines may select a single memory element within the array at the intersection of the decoded row and column lines. In this illustrative embodiment the memory is organized as a bit-wide memory: a memory that provides access to a single bit for each access cycle. Other memory architectures, such as byte-wide or word-wide or serial architectures, are contemplated within the scope of the invention. In this illustrative embodiment, data is written, in parallel, to a data latch 303 and to a selected memory element within the array 302. An address latch 304 latches addresses received from an accessing device and holds the addresses for use by a decoder 306. The decoder translates the address value to the appropriate selection circuitry values in order to access the specific memory element within the array 302 corresponding to the address value. Address values are also provided by the address latch 304 to a delay latch 308 which retains the address from the previous memory chip access. The latch is updated at the end of each write cycle to place the present address in the delay latch for access after the next memory access. The delay latch 308 provides a delayed copy of the address to a comparator 310, which compares the current address value from the address latch 304 to the address of the immediately prior write access in the delay latch 308, and feeds the result of the comparison to an input/output control circuit 312.

The input/output control circuit 312 is configured to operate a multiplexor 314 to thereby select the source of data output to an accessing circuit from either the nonvolatile memory array 302 or from the data latch 303. The criteria for selecting data from either the data latch or a selected memory element is described in greater detail in the discussion related to FIG. 2.

A mode input circuit 316 indicates the current mode of operation to the input/output control circuit 312. As described in the discussion related to FIG. 2, mode indicia may be used to determine whether the memory's current access cycle is of a mode that is compatible with reading data directly from the data latch 303, rather than from a decoded nonvolatile memory element within the array 302. Read, Write, and Chip Enable inputs may also be employed by the input/output control circuit 312 to determine whether data should be read from a selected memory element within the array 302 or from the data latch 303. A sense amplifier 318 may be positioned, as in this illustrative embodiment, on the output side of the multiplexor 314 and configured to sense the state of the multiplexor output and to drive that signal to the memory's output port. Alternatively, the sense amp (SA) 318 may be on the output of the array before the multiplexor, and the multiplexor may select between fully amplified signals from the latch 303 or the array sense amp 318 to drive the Data path to the output.

In this illustrative embodiment, a delay latch 320 accepts the address signals during write and holds it until the next write access cycle—and thereby holds it during any read access cycles in between. The delayed write address signal and current read address signals are fed to a comparator 322 which provides an indication to the control circuit 312 of whether the current read address and previous write address are both the same. In accordance with this illustrative embodiment, if the current access operation is a read operation and a previous access operation was write, one criterion for the control circuit 312 to enable reading from the data latch 303 is met. Such criteria may include requiring the immediately previous access to be write and present address to be read.

Also, the address for each is compared and if the same, the latch may be read instead of the array. Again, the criteria may require that the immediately previous access be write and the present address be read. Or, the criteria may be broadened to read the latch whenever the addresses are the same, if at least one previous write occurred that stored the previous write address and the information written (respectively in the delay latch 308 and the data latch 303).

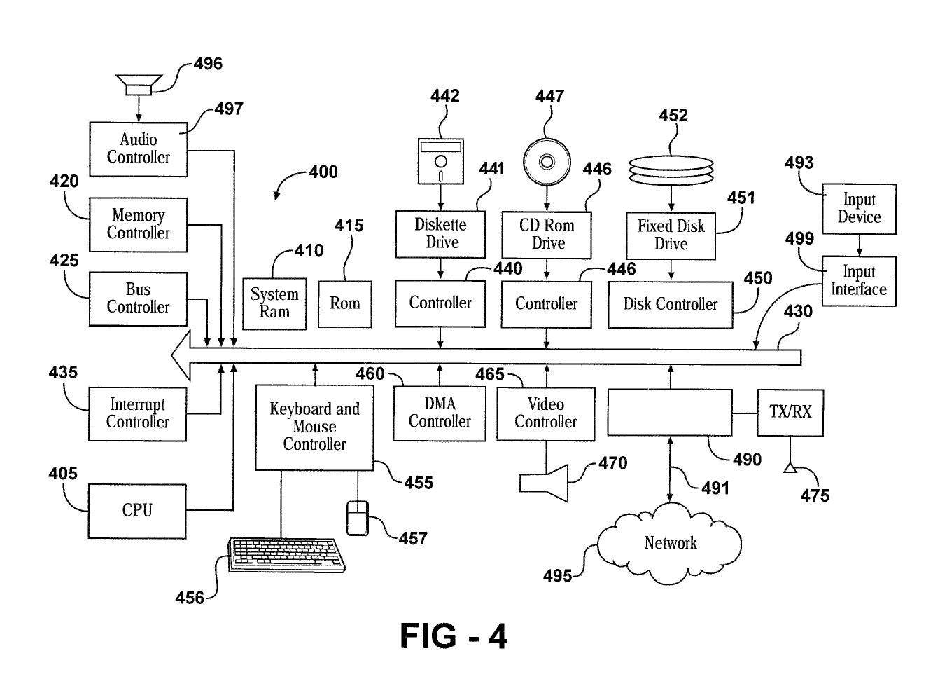

The electronic device(s) described in the discussion related to the previous figures may be employed to particular advantage in a wide variety of systems. The schematic diagram of FIG. 4 will be discussed to illustrate the devices' use in a few such systems. The schematic diagram of FIG. 4 includes many components and devices, some of which may be used for specific embodiments of a system in accordance with the principles of the present invention and others not used. In other embodiments, other similar systems, components and devices may be employed. In general, the system includes logic circuitry configured to operate along with phase change memory devices in accordance with the principles of the present invention. The logic circuitry may be discrete, programmable, application-specific, or in the form of a microprocessor, microcontroller, or digital signal processor, for example. The embodiments herein may be employed on integrated chips or connected to such circuitry. The exemplary system of FIG. 4 is for descriptive purposes only.

Although the description may refer to terms commonly used in describing particular computer, communications, tracking, and entertainment systems; the description and concepts equally apply to other systems, including systems having architectures dissimilar to that illustrated in FIG. 4. The electronic system 400, in various embodiments, may be implemented as, for example, a general purpose computer, a router, a large-scale data storage system, a portable computer, a personal digital assistant, a cellular telephone, an electronic entertainment device, such as a music or video playback device or electronic game, a microprocessor, a microcontroller, a digital signal processor, or a radio frequency identification device. Any or all of the components depicted in FIG. 4 may employ non-volatile memory, such as phase change memory devices, in accordance with the principles of the present invention, for example.

In an illustrative embodiment, the system 400 may include a central processing unit (CPU) 405, which may include a microprocessor, a random access memory (RAM) 410 for temporary storage of information, and a read only memory (ROM) 415 for permanent storage of information. A memory controller 420 is provided for controlling RAM 410. In accordance with the principles of the present invention, all of, or any portion of, any of the memory elements (RAM, ROM, or disk (solid state disc or rotating media with a buffer memory incorporating the embodiments and principles of the present invention herein, for example) may be implemented with nonvolatile memory in accordance with the principles of the present invention.

An electronic system 400 in accordance with the principles of the present invention may be a microprocessor that operates as a CPU 405, in combination with nonvolatile memory in accordance with the principles of the present invention that operates as RAM 410 and/or ROM 415, or as a portion thereof. In this illustrative example, the microprocessor/nonvolatile memory combination may be standalone, or may operate with other components, such as those of FIG. 4 yet-to-be described.

In implementations within the scope of the invention, a bus 430 interconnects the components of the system 400. A bus controller 425 is provided for controlling bus 430. An interrupt controller 435 may or may not be used for receiving and processing various interrupt signals from the system components. Such components as the bus 430, bus controller 425, and interrupt controller 435 may be employed in a large-scale implementation of a system in accordance with the principles of the present invention, such as that of a standalone computer, a router, a portable computer, or a data storage system, for example.

Mass storage may be provided by diskette 442, CD ROM 447, or hard drive 452. Data and software may be exchanged with the system 400 via removable media such as diskette 442 and CD ROM 447. Diskette 442 is insertable into diskette drive 441 which is, in turn, connected to bus 430 by a controller 440. Similarly, CD ROM 447 is insertable into CD ROM drive 446 which is, in turn, connected to bus 430 by controller 445. Hard disc 452 is part of a fixed disc drive 451 which is connected to bus 430 by controller 450. Although conventional terms for storage devices (e.g., diskette) are being employed in this description of a system in accordance with the principles of the present invention, any or all of the storage devices may be implemented using nonvolatile memory in accordance with the principles of the present invention. Removable storage may be provided by a nonvolatile storage component, such as a thumb drive, that employs nonvolatile memory in accordance with the principles of the present invention as the storage medium. Storage systems that employ nonvolatile memory in accordance with the principles of the present invention as “plug and play” substitutes for conventional removable memory, such as disks or CD ROMs or thumb drives, for example, may emulate existing controllers to provide a transparent interface for controllers such as controllers 440, 445, and 450, for example.

User input to the system 400 may be provided by any of a number of devices. For example, a keyboard 456 and mouse 457 are connected to bus 430 by controller 455. An audio transducer 496, which may act as both a microphone and/or a speaker, is connected to bus 430 by audio controller 497, as illustrated. Other input devices, such as a pen and/or tabloid may be connected to bus 430 and an appropriate controller and software, as required, for use as input devices. DMA controller 460 is provided for performing direct memory access to RAM 410, which, as previously described, may be implemented in whole or part using nonvolatile memory in accordance with the principles of the present invention. A visual display is generated by video controller 465 which controls display 470. The display 470 may be of any size or technology appropriate for a given application.

In a cellular telephone or portable entertainment system embodiment, for example, the display 470 may include one or more relatively small (e.g. on the order of a few inches per side) LCD displays. In a large-scale data storage system, the display may be implemented as large-scale multi-screen, liquid crystal displays (LCDs), or organic light emitting diodes (OLEDs), including quantum dot OLEDs, for example.

The system 400 may also include a communications adaptor 490 which allows the system to be interconnected to a local area network (LAN) or a wide area network (WAN), schematically illustrated by bus 491 and network 495. An input interface 499 operates in conjunction with an input device 493 to permit a user to send information, whether command and control, data, or other types of information, to the system 400. The input device and interface may be any of a number of common interface devices, such as a joystick, a touch-pad, a touch-screen, a speech-recognition device, or other known input device. In some embodiments of a system in accordance with the principles of the present invention, the adapter 490 may operate with transceiver 473 and antenna 475 to provide wireless communications, for example, in cellular telephone, RFID, and wifi computer implementations.

Operation of system 400 is generally controlled and coordinated by operating system software. The operating system controls allocation of system resources and performs tasks such as processing scheduling, memory management, networking, and I/O services, among other things. In particular, an operating system resident in system memory and running on CPU 405 coordinates the operation of the other elements of the system 400.

In illustrative handheld electronic device embodiments of a system 400 in accordance with the principles of the present invention, such as a cellular telephone, a personal digital assistance, a digital organizer, a laptop computer, a handheld information device, a handheld entertainment device such as a device that plays music and/or video, small-scale input devices, such as keypads, function keys and soft keys, such as are known in the art, may be substituted for the controller 455, keyboard 456 and mouse 457, for example. Embodiments with a transmitter, recording capability, etc., may also include a microphone input (not shown).

In an illustrative RFID transponder implementation of a system 400 in accordance with the principles of the present invention, the antenna 475 may be configured to intercept an interrogation signal from a base station at a frequency F. The intercepted interrogation signal would then be conducted to a tuning circuit (not shown) that accepts signal F₁ and rejects all others. The signal then passes to the transceiver 473. where the modulations of the carrier F₁ comprising the interrogation signal are detected, amplified and shaped in known fashion. The detected interrogation signal then passes to a decoder and logic circuit which may be implemented as discrete logic in a low power application, for example, or as a microprocessor/memory combination as previously described. The interrogation signal modulations may define a code to either read data out from or write data into nonvolatile memory in accordance with the principles of the present invention. In this illustrative embodiment, data read out from the memory is transferred to the transceiver 473 as an “answerback” signal on the antenna 475 at a second carrier frequency F₂. In passive RFID systems, power is derived from the interrogating signal and memory such as provided by nonvolatile memory in accordance with the principles of the present invention is particularly well suited to such use.

I claim:

1. An electronic system, comprising:
a plurality of nonvolatile memory elements;
a latch;
write circuitry configured to write to a memory element and the latch in parallel; and
read circuitry configured to read from a memory element or the latch.

2. The electronic system of claim 1 further comprising access control circuitry configured to compare the memory's current and immediately prior addresses and to enable reading from the latch if at least a portion of the memory's current and immediately prior addresses match.

3. The electronic system of claim 2 wherein the memory is configured to operate in an accelerated access mode and the access control circuitry is configured to enable reading from the latch while the memory is operating in the accelerated access mode.

4. The electronic system of claim 3 wherein the memory is configured to operate in page mode and the access control circuitry is configured to enable reading from the latch if the memory's current and immediately prior addresses fall within the same page.

5. The electronic system of claim 1 further comprising comparison circuitry configured to compare the memory's current and immediately prior access operations and to enable reading from the latch if the current access operation is a read access operation and the immediately prior access operation was a write access operation.

6. The electronic system of claim 5 further comprising circuitry configured to enable a selection between the data stored within a memory element or data stored in the latch during a read access operation, depending upon the memory's current access mode.

7. The electronic system of claim 6 wherein the selection of data stored in the latch is enabled when the memory's current access mode is an accelerated access mode.

8. The electronic system of claim 2 wherein the memory elements are programmable resistance memory elements.

9. The electronic system of claim 8 wherein the memory elements are phase change memory elements.

10. The electronic system of claim 1, wherein the state of said nonvolatile memory elements varies spontaneously in time.

11. The electronic system of claim 1, wherein said read circuitry is configured to read selectively from a memory element or the latch.

12. The electronic system of claim 1, further comprising:
memory address comparison circuitry configured to compare the address of the current access operation with the address of a prior access operation.

13. The electronic system of claim 12, wherein the address is a line address.

14. The electronic system of claim 12, further comprising:
circuitry configured to determine whether the current access operation is a read operation.

15. The electronic system of claim 14, further comprising:
circuitry configured to determine whether a prior access operation was a write operation.

16. The electronic system of claim 15, further comprising:
circuitry configured to determine whether the prior write operation occurred at the address of the current read operation.

17. The electronic system of claim 16, further comprising:
data selection circuitry configured to read data from the latch if the prior write operation occurred at the address of the current read operation.

18. The electronic system of claim 17, wherein the prior write operation is the access operation immediately preceding the current read operation.

19. The electronic system of claim 16, further comprising:
data selection circuitry configured to read data from the latch if the prior write operation occurred at an address on the same page as the address of the current read operation.

20. The electronic system of claim 16, further comprising:
data selection circuitry configured to read data from the memory element if the prior write operation occurred at an address other than the address of the current read operation.

21. The electronic system of claim 1 further comprising:
controller circuitry configured to access the memory array and a latch.

22. The system of claim 21 further comprising a transceiver.

23. The system of claim 22 wherein the electronic system is configured as a radio frequency identification device.

24. The system of claim 22 wherein the electronic system is configured as a cellular telephone.

25. The system of claim 21 wherein the system is configured as a computer.

26. The system of claim 21, wherein said write circuitry addresses to a separate latch with comparison circuitry to a later read address.
